(19) United States
(12) Patent Application Publication
(10) Pub. No.: US 2017/0066063 A1
(43) Pub. Date: Mar. 9, 2017

(54) DRILL STRUCTURE

(71) Applicant: TCT GLOBAL LIMITED, Hong Kong (HK)

(72) Inventors: Nick Sung-Hao CHIEN, Taoyuan Hsien (TW); Li-Yi CHAO, Taoyuan Hsien (TW); Feng-Yu LIN, Taoyuan Hsien (TW); Ming-Yuan ZHAO, Taoyuan Hsien (TW); Chun-Yu CHEN, Taoyuan Hsien (TW)

(21) Appl. No.: 14/990,424

(22) Filed: Jan. 7, 2016

(30) Foreign Application Priority Data
Sep. 8, 2015 (TW) 104214496

(51) Int. Cl. B23B 51/02; H05K 3/00

(52) U.S. Cl. CPC B23B 51/02; H05K 3/0047; B23B 2222/80; B23B 2240/16; B23B 2240/21; B23B 2251/426

(57) ABSTRACT

A drill structure includes a shank part and a flute part. A chisel edge is formed on the front end of the flute part and two primary relief faces with tile directions toward the shank part are symmetrically formed on the two sides of the chisel edge. Each primary relief face has a cutting edge, a knife-back edge, and an outer edge. The outer edges are respectively helically extended around the periphery of the flute part to form two helical cutting edges and two helical grooves. Two assist relief faces are respectively formed on the inner walls of the two helical grooves, and every assist relief face is connected with the cutting edge of one primary relief face and portion of the knife-back edge of another primary relief face. The drill structure can decrease the thickness of the chisel edge, reduces the resistance during drilling, and increases the life.

### BACKGROUND OF THE INVENTION

1. Field of the Invention

The present invention relates to a drill structure, particularly to a drill structure adaptive to printed circuit boards.

2. Description of the Prior Art

With advance of science and technology, the circuits on a printed circuit board (PCB) are growing miniaturized to achieve high density and high precision. Confronting the highly competitive environment demanding high quality, high productivity and fast supply, the manufacturers require the micro drills used in PCB to have higher and higher precision, strength, feed rate, and surface finish. In practical fabrication, the manufacturer is likely to stack a plurality of PCBs and drill them simultaneously so as to increase the fabrication efficiency and decrease the fabrication cost. In such a case, the micro drill needs to have longer length and sufficient chip discharge capability.

A micro drill involves a shank part and a flute part connected with the shank part. The front end of the flute part has a cutting structure 10, as shown in FIG. 1. The cutting structure 10 includes two primary cutting faces 12 and 12′ and two secondary cutting faces 14 and 14′, which are symmetrically arranged with respect to a static tip point 16 and used to cut workpieces. The secondary cutting faces 14 and 14′ of the conventional cutting structure 10 would significantly decrease the strength of the cutting structure 10, making the cutting faces break easily and shortening the service life of the drill. The edge 121 of the primary cutting face 12 and the edge 141 of the secondary cutting face 14 define the central region of the cutting faces. In the conventional micro drill, the central region of the cutting faces has a larger thickness T, which causes the micro drill to experience a greater resistant force during drilling and shortens the service life of the micro drill.

### SUMMARY OF THE INVENTION

One objective of the present invention is to provide a drill structure to solve the abovementioned problems, wherein the conventional secondary cutting faces are eliminated to enhance the structural strength of the cutting structure and increase the service life of the drill structure, and wherein the assist relief face is tilted to reduce of the thickness of the chisel edge and thus decrease the resistant force during drilling and increase the service life of the drill structure.

In order to achieve the abovementioned objective, the drill structure in one embodiment of the present invention includes a shank part; and a flute part arranged on one end of the shank part and a chisel edge (the central region of the cutting faces) formed on a front end of the flute part. Two primary relief faces with tile directions toward the shank part are symmetrically formed on two sides of the chisel edge, and each primary relief face has a cutting edge, a knife-back edge, and an outer edge. The outer edges are respectively helically extended around a periphery of the flute part toward the shank part to form two helical cutting edges and two helical grooves. Two assist relief faces are respectively formed on the inner walls of the two helical grooves and every assist relief face is extended from the cutting edge of one primary relief face and portion of the knife-back edge of another primary relief face. The assist relief face and a horizontal plane, which is perpendicular to a rotation axis of the drill structure, have an included angle therebetween. In one embodiment, the assist relief face has a width equal to 20-80% of the outer diameter of the flute part.

From a portion of every outer edge, which is adjacent to the knife-back edge of the primary relief face, a lateral groove is formed along the helical cutting edges. In one embodiment, the flute part is divided into a bit head and a bit body. The frontmost region of the bit head is the chisel edge. The outer diameter of the bit head is larger than the outer diameter of the bit body. The lateral grooves are respectively disposed in the helical cutting edges in the bit head. The drop depth of the outer diameters of the bit head and the outer diameter of the bit body is about equal to 1-20% of the outer diameter of the flute part.

Each primary relief face and a horizontal plane, which is perpendicular to a rotation axis of the drill structure, have an included angle of 5-30 degrees, and two primary relief faces include a point angle of 100-170 degrees.

In one embodiment, the flute part is divided into a front section, a middle section and a rear section sequentially from the chisel edge to the shank part; two helical grooves are symmetric to and separated from each other in the front section, gradually approach to each other in the middle section, and partially overlap in the rear section.

In one embodiment, the shank part is made of a stainless steel, and the flute part is made of tungsten carbide; the flute part is bound to the shank part with a welding technology or an adhesive agent. In one embodiment, one end face of the shank part has a hole; one end of the flute part has an insert; the inner diameter of the hole is equal to or smaller than the outer diameter of the insert; the insert is intruded into the hole and embedded thereinside so as to bind the shank part and the flute part together.

### BRIEF DESCRIPTION OF THE DRAWINGS

FIG. 1 is a diagram schematically showing cutting faces of a conventional drill structure;

FIG. 2 is a diagram schematically showing a drill structure according to one embodiment of the present invention;

FIG. 3a and FIG. 3b are respectively a top view and a local side view of an end of a drill structure according to a first embodiment of the present invention;

FIG. 4a and FIG. 4b are respectively a top view and a local side view of an end of a drill structure according to a second embodiment of the present invention; and

FIG. 5 is a diagram schematically showing a drill structure according to a further embodiment of the present invention.

### DESCRIPTION OF THE PREFERRED EMBODIMENTS

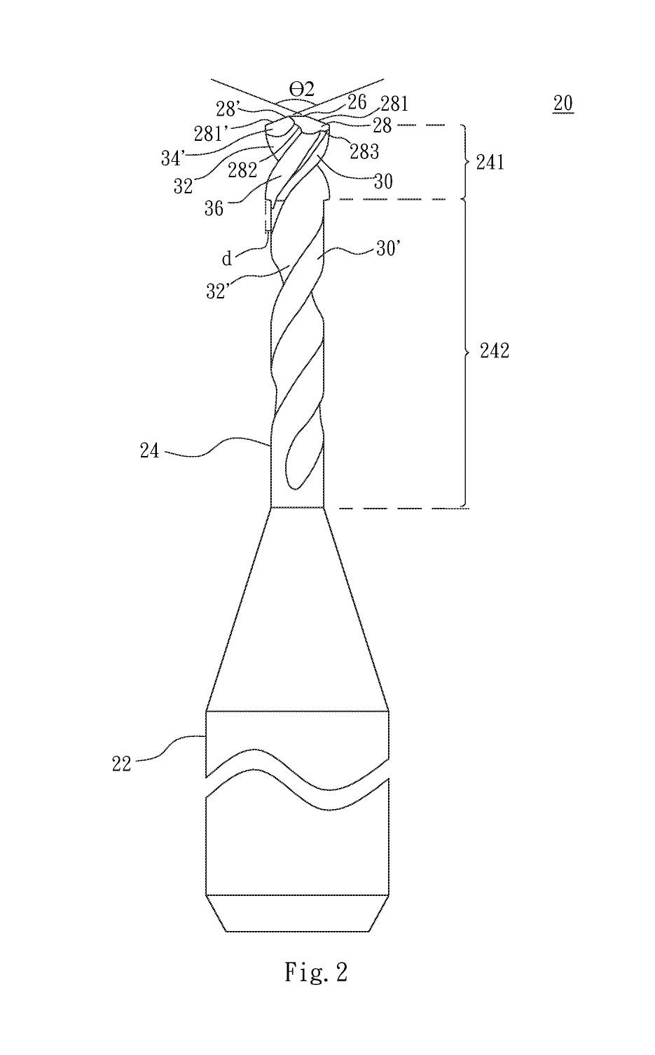

FIG. 2 is a diagram schematically showing a drill structure according to one embodiment of the present invention. As shown in FIG. 2, the drill structure 20 comprises a shank part 22 and a flute part 24 arranged on one end of the shank part 22. The frontmost region of the flute part 24 is a chisel edge 26 (the central region of the cutting faces). Two primary relief faces 28, 28′ with tile directions toward the shank part 22 are symmetrically formed on the two sides of the chisel edge 26.

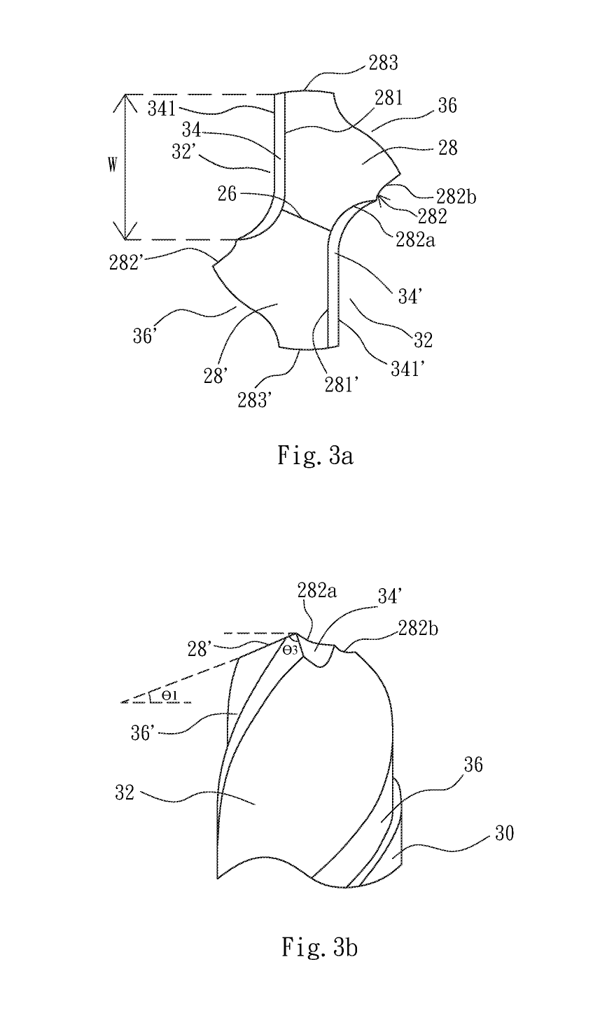

FIG. 3a and FIG. 3b are respectively a top view and a local side view of an end of a drill structure according to a first embodiment of the present invention. As shown in FIG. 3a and FIG. 3b, each of the primary relief faces 28, 28′ has a cutting edge 281, 281′, a knife-back edge 282, 282′, and an outer edge 283, 283′. The outer edges 283, 283′ of the primary relief faces 28, 28′ are respectively helically extended around the periphery of the flute part 24 toward the shank part 22 to form two helical cutting edges 30, 30′ and two helical grooves 32, 32′. Two assist relief faces 34, 34′ are respectively formed on the inner walls of the two helical grooves 32, 32′ and every assist relief face 34, 34′is extended from the cutting edge 281, 281′ of one primary relief face 28, 28′ and portion of the knife-back edge 282′, 282 of another primary relief face 28′, 28.

As shown in FIG. 3b, each of two primary relief faces 28, 28′ is tilted from the chisel edge 26 toward the shank part 22, having a tilt angle θ1 of 5-30 degrees. As shown in FIG. 2, the two primary relief faces 28, 28′ includes a point angle θ2 of 100-170 degrees.

As shown in FIG. 3a, each of the knife-back edges 282, 282′of the primary relief faces 28, 28′ has a double-arc shape. For example, the knife-back edge 282 of the primary relief face 28 has a first arc 282a and a second arc 282b. The first arc 282a cooperates with the cutting edge 281′ of the other primary relief face 28′ to extend and form the assist relief face 34′. As shown in FIG. 3b, the assist relief faces 34′ and a horizontal plane, which is perpendicular to a rotation axis of the drill structure, have an included angle θ3. The included angle θ3 is within 90 and 180 degrees in the first embodiment. As shown in FIG. 3a, the lower edge 341, 341′ of the assist relief face 34, 34′ is tilted toward the outer side of the primary relief faces 28. 28′. Thus, each of the assist relief faces 34 and 34′ has a negative tilt angle.

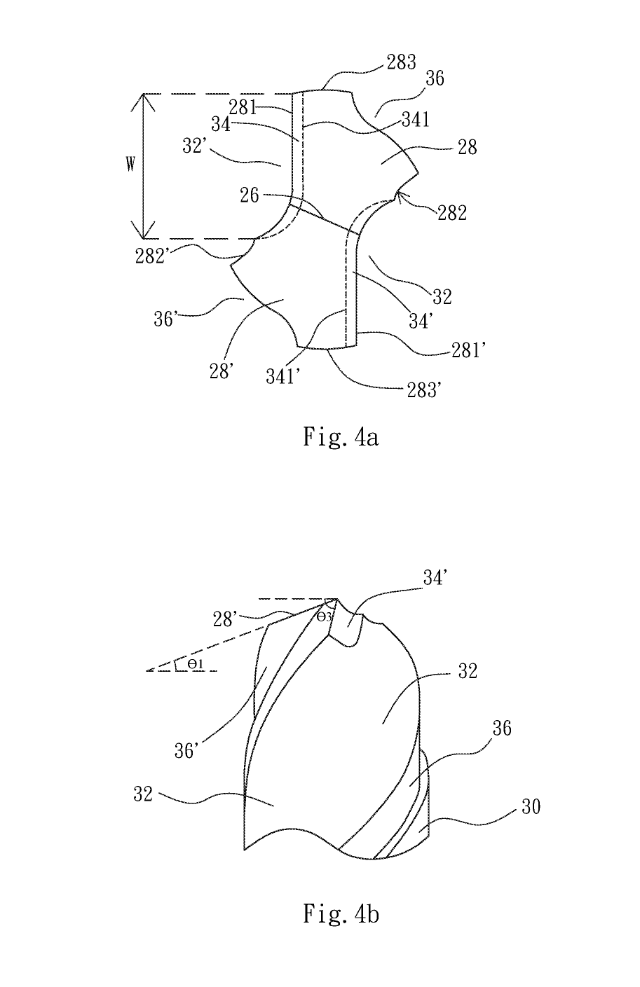

FIG. 4a and FIG. 4b are respectively a top view and a local side view of an end of a drill structure according to a second embodiment of the present invention. In the second embodiment, two primary relief faces 28, 28′ with tile directions toward the shank part 22 are symmetrically formed on the two sides of the chisel edge 26. Each of the primary relief faces 28, 28′ has a cutting edge 281, 281′, a knife-back edge 282, 282′, and an outer edge 283, 283′. Two assist relief faces 34, 34′ are respectively formed on the inner walls of the two helical grooves 32, 32′ and every assist relief face 34, 34′is extended from the cutting edge 281, 281′ of one primary relief face 28, 28′ and portion of the knife-back edge 282′, 282 of another primary relief face 28′, 28. The second embodiment is different from the first embodiment in that the assist relief face 34, 34′ and a horizontal plane has an included angle θ3, which is within 0 and 90 degrees in the second embodiment (as shown in FIG. 4b) and that the lower edge 341, 341′ of the assist relief face 34, 34′ is tilted toward the inner side of the primary relief faces 28, 28′ (as shown in FIG. 4a). Thus, each of the assist relief faces 34, 34′ has a positive tilt angle in the second embodiment.

In one embodiment, no matter whether the assist relief faces 34, 34′ have a positive or negative tilt angle, each of the assist relief faces 34, 34′ has a width W equal to 20-80%, preferably 60%, of the outer diameter of the flute part 24. Refer to FIG. 2, FIG. 3a and FIG. 4a, two lateral grooves 36, 36′ are respectively formed along the two helical cutting edges 30, 30′, and every lateral groove 36, 36′ is from a portion of the outer edge 283, 283′, which is adjacent to the knife-back edge 282, 282′ of the primary relief face 28, 28′. In one embodiment, the length of the lateral groove 36, 36′ is smaller than the length of the helical groove 32, 32′. In one embodiment, the flute part 24 is divided into a bit head 241 and a bit body 242; the frontmost region of the bit head 241 is the chisel edge 26; the bit head 241 has a length of about 0.2-1.4 mm; the outer diameter of the bit head 241 is larger than the outer diameter of the bit body 242; the drop depth d of the outer diameters of the bit head 241 and the bit body 242 is about equal to 1-20% of the outer diameter of the flute part 24; the lateral grooves 36, 36′ are respectively disposed in the helical cutting edges 30, 30′ in the bit head 241.

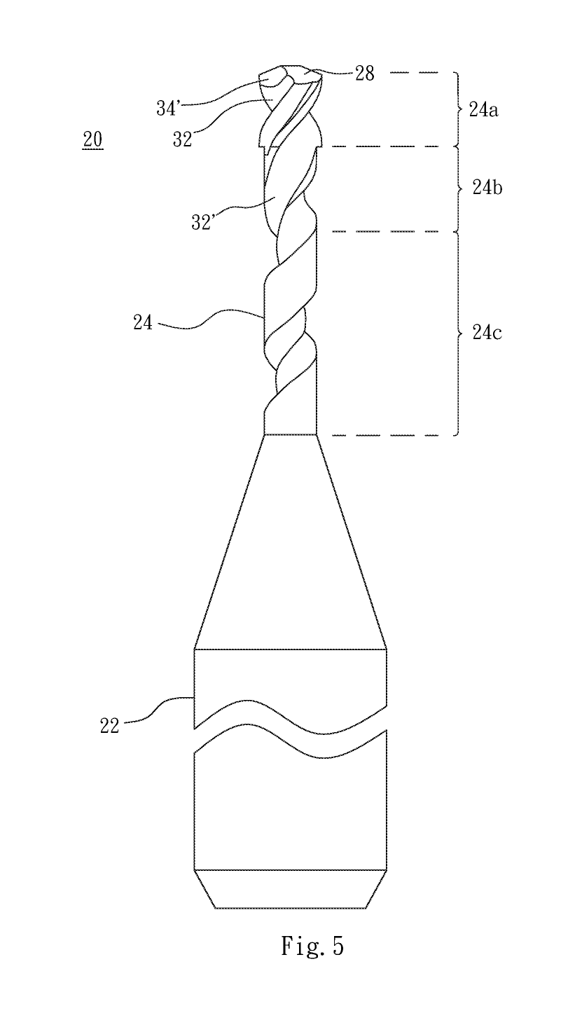

Refer to FIG. 5 a diagram schematically showing a drill structure according to a further embodiment of the present invention. In the embodiment shown in FIG. 5, the flute part 24 is divided into a front section 24a, a middle section 24b and a rear section 24c sequentially from the chisel edge to the shank part 22. The length of the front section 24a is equal to, longer than or smaller than the length of the bit head 241 (shown in FIG. 2). The helical grooves 32, 32′ are symmetric to and separated from each other in the front section 24a, gradually approach to each other in the middle section 24b, and partially overlap in the rear section 24c. In the embodiment shown in FIG. 5, the front section 24a is corresponding to the bit head 241 shown in FIG. 2; the middle section 24b and the rear section 24c are corresponding to the bit body 241 shown in FIG. 2, wherein the two helical grooves 32, 32′ are symmetric to and separated from each other in the bit head 241, gradually approach to each other and then partially overlap in the bit body 242.

In one embodiment, the shank part 22 is made of a stainless steel; the flute part 24 is made of tungsten carbide. In one embodiment, the flute part 24 is bound to the shank part 22 with a welding technology or an adhesive agent. In one embodiment, one end face of the shank part 22 has a hole (not shown in the drawings); one end of the flute part 24 has an insert;

the inner diameter of the hole is equal to or smaller than the outer diameter of the insert; the insert is intruded into the hole and embedded thereinside, whereby the flute part 24 is bounded to the shank part 22. In one embodiment, the shank part 22 and the flute part 24 of the drill structure 20 are fabricated into a one-piece component with tungsten carbide.

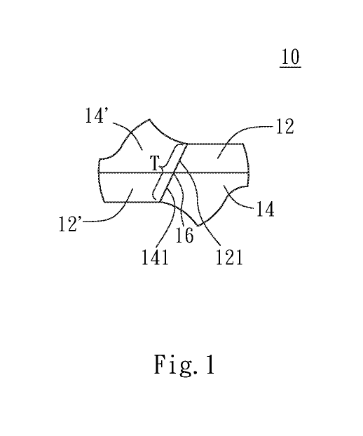

In the present invention, the secondary cutting faces shown in FIG. 1 are eliminated to enhance the strength of the cutting structure and increase the service life of the drill structure; the design of tilted assist relief faces reduces of the thickness of the chisel edge and thus decreases the resistant force during drilling and increases the service life of the drill bit.

Although the present invention has been explained in relation to its preferred embodiment, it is to be understood that other modifications and variation can be made without departing the spirit and scope of the invention as hereafter claimed.

What is claimed is:

1. A drill structure comprising
a shank part; and
a flute part arranged on one end of the shank part and a chisel edge formed on a front end of the flute part, wherein two primary relief faces with tile directions toward the shank part are symmetrically formed on two sides of the chisel edge, and each primary relief face has a cutting edge, a knife-back edge, and an outer edge, and wherein the outer edges are respectively helically extended around a periphery of the flute part toward the shank part to form two helical cutting edges and two helical grooves, and wherein two assist relief faces are respectively formed on the inner walls of the two helical grooves and every assist relief face is extended from the cutting edge of one primary relief face and portion of the knife-back edge of another primary relief face.

2. The drill structure according to claim 1, wherein the assist relief face and a horizontal plane, which is perpendicular to a rotation axis of the drill structure, have an included angle therebetween.

3. The drill structure according to claim 1, wherein the assist relief face has a width equal to 20-80% of an outer diameter of the flute part.

4. The drill structure according to claim 1, wherein two lateral grooves are respectively formed along the two helical cutting edges, and every lateral groove is from a portion of the outer edge adjacent to the knife-back edge of each the primary relief face.

5. The drill structure according to claim 4, wherein the flute part is divided into a bit head and a bit body; a frontmost region of the bit head is the chisel edge; an outer diameter of the bit body is smaller than an outer diameter of the bit head; the lateral grooves are respectively disposed in the helical cutting edges in the bit head.

6. The drill structure according to claim 5, wherein a drop exists between the outer diameter of the bit head and the outer diameter of the bit body;
a drop depth of the drop is equal to 1-20% of an outer diameter of the flute part.

7. The drill structure according to claim 1, wherein each the primary relief face and a horizontal plane, which is perpendicular to a rotation axis of the drill structure, have an included angle of 5-30 degrees, and the two primary relief faces includes a point angle of 100-170 degrees.

8. The drill structure according to claim 1, wherein the flute part is divided into a front section, a middle section and a rear section sequentially from the chisel edge to the shank part; the two helical grooves are symmetric to and separated from each other in the front section, gradually approach to each other in the middle section, and partially overlap in the rear section.

9. The drill structure according to claim 1, wherein the shank part is made of a stainless steel, the flute part is made of tungsten carbide, and the flute part is bound to the shank part with a welding technology or an adhesive agent.

10. The drill structure according to claim 1, wherein one end face of the shank part has a hole; one end of the flute part has an insert; an inner diameter of the hole is equal to or smaller than an outer diameter of the insert; the insert is intruded into the hole and embedded thereinside.
